(19) United States
(12) Patent Application Publication
(10) Pub. No.: US 2025/0300576 A1
(43) Pub. Date: Sep. 25, 2025

(54) ENERGY HARVESTING SYSTEM UTILIZING PVDF PIEZOELECTRIC FILM

(71) Applicant: Kureha America, Inc., Houston, TX (US)

(72) Inventors: Tatsuya Yaguchi, Houston, TX (US); Masako Akiyama, Houston, TX (US)

(73) Assignee: Kureha America, Inc., Houston, TX (US)

(21) Appl. No.: 19/089,998

(22) Filed: Mar. 25, 2025

Related U.S. Application Data
(60) Provisional application No. 63/569,403, filed on Mar. 25, 2024.

(51) Int. Cl. H02N 2/18

(52) U.S. Cl. CPC H02N 2/185

(57) ABSTRACT

An energy harvesting system includes: a bluff body; and a multilayer stack including piezoelectric layers stacked along a first direction. Each piezoelectric layer includes: a flexible piezoelectric film substrate that extends away from the bluff body along a second direction; an anode that covers a first side of the piezoelectric film substrate; and a cathode that covers a second side of the piezoelectric film substrate. The piezoelectric layers are electrically connected in parallel. The piezoelectric layers are configured to deform in response to a flow of a medium around the bluff body along the second direction.

### BACKGROUND

Countries and companies around the global are increasingly focused on techniques for generating energy with low environmental impact (e.g., harvesting renewable energy sources). One approach is to harvest the energy of a mechanical motion found in nature, such as of a hydroelectric power plant utilizing the flow of water through a turbine or a wind power plant utilizing the flow of air through a windmill. Additional energy harvesting techniques that can be scaled and adapted to different power supply requirements is desirable.

### SUMMARY

In general, one or more embodiments of the invention relate to an energy harvesting system. The energy harvesting system includes: a bluff body; and a multilayer stack including piezoelectric layers stacked along a first direction. Each piezoelectric layer includes: a flexible piezoelectric film substrate that extends away from the bluff body along a second direction; an anode that covers a first side of the piezoelectric film substrate; and a cathode that covers a second side of the piezoelectric film substrate. The piezoelectric layers are electrically connected in parallel. The piezoelectric layers are configured to deform in response to a flow of a medium around the bluff body along the second direction.

In general, one or more embodiments of the invention relate to a method for manufacturing an energy harvesting system. The method includes: obtaining a bluff body; obtaining piezoelectric layers that each include a flexible piezoelectric film substrate, an anode that covers a first side of the piezoelectric film substrate, and a cathode that covers a second side of the piezoelectric film substrate; assembling a multilayer stack by stacking the piezoelectric layers along a first direction; electrically connecting the piezoelectric layers in parallel; and attaching the multilayer stack to the bluff body. The piezoelectric layers are configured to deform in response to a flow of a medium around the bluff body along the second direction.

In general, one or more embodiments of the invention relate to a method for generating electricity using an energy harvesting system that includes a bluff body and a multilayer stack of piezoelectric layers. The method includes: attaching the bluff body to an anchor point; distributing the piezoelectric layers along a first direction such that a flexible piezoelectric film substrate of each piezoelectric layer extends away from the bluff body along a second direction; electrically connecting an anode and a cathode of each piezoelectric layer in parallel to form an electrical path through the energy harvesting system; and flowing a medium around the bluff body along the second direction to generate Karman Vortex Street that deforms the piezoelectric layers.

Other aspects of the invention will be apparent from the following description and the appended claims.

### BRIEF DESCRIPTION OF DRAWINGS

FIG. 1A shows a diagram of a Karman Vortex Street.

FIG. 1B shows a schematic of a comparative example of a piezoelectric sheet.

FIG. 1C shows a schematic of comparative example of a conventional energy harvester.

FIG. 2A shows a piezoelectric layer, in accordance with one or more embodiments.

FIG. 2B shows a multilayer stack of piezoelectric layers, in accordance with one or more embodiments.

FIGS. 3A-3B show examples of deformation over time in a multilayer stack 100 according to example embodiments.

FIGS. 4A-4C show examples of a multilayer stack 100, in accordance with one or more embodiments.

FIG. 5 shows a flowchart of a method for generating electricity using an energy harvesting system that includes a bluff body and a multilayer stack of piezoelectric layers, in accordance with one or more embodiments.

### DETAILED DESCRIPTION

Specific embodiments of the invention will now be described in detail with reference to the accompanying figures. Like elements in the various figures are denoted by like reference numerals for consistency.

In the following detailed description of embodiments of the invention, numerous specific details are set forth in order to provide a more thorough understanding of the invention. However, it will be apparent to one of ordinary skill in the art that the invention may be practiced without these specific details. In other instances, well-known features have not been described in detail to avoid unnecessarily complicating the description.

Throughout the application, ordinal numbers (e.g., first, second, third) may be used as an adjective for an element (i.e., any noun in the application). The use of ordinal numbers is not to imply or create a particular ordering of the elements nor to limit any element to being only a single element unless expressly disclosed, such as by the use of the terms “before,” “after,” “single,” and other such terminology. Rather the use of ordinal numbers is to distinguish between the elements. By way of an example, a first element is distinct from a second element, and the first element may encompass more than one element and may succeed (or precede) the second element in an ordering of elements.

Mechanical motion found in nature presents in various forms. In any fluid system, flow of the fluid medium around a stationary obstacle may create oscillating flow fields under certain conditions (e.g., flow speed). Harvesting the energy in the flow fields is a potential source of renewable energy.

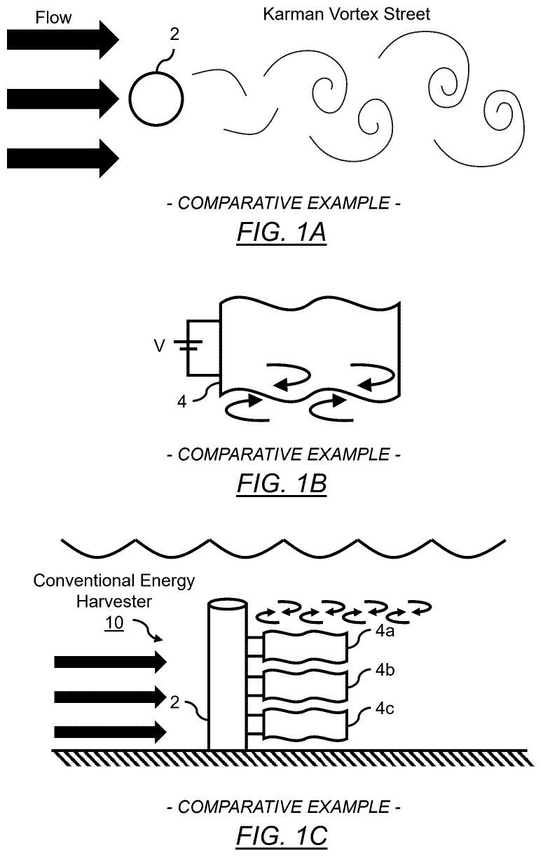

FIG. 1A shows a diagram of a Kirmin (Karman) Vortex Street (KVS).

A KVS is a periodic eddy pattern caused by the flow of a medium around a bluff body 2. Vortices (i.e., eddies) are periodically shed from the bluff body 2 along the direction of flow (i.e., the direction of the KVS). Depending on the geometry of the bluff body 2 (e.g., a characteristic length parameter) and the physical properties of the medium (e.g., viscosity), the parameters of the KVS (e.g., periodicity, vortex speed, vortex size) will vary. The vortices of the KVS form a turbulent flow pattern that can be captured by a flexible medium disposed within the KVS. One example of a flexible medium is a piezoelectric sheet 4.

FIG. 1B shows a schematic of a comparative example of a piezoelectric sheet 4.

Piezoelectric materials have a charge separating affect due to an anisotropic charge distribution in the piezoelectric material. For example, a polymer may have an anisotropic charge distribution between opposing sides of a carbon-carbon backbone of the polymer chain. The polymer may be formed into a geometry that preserves the anisotropic charge distribution effect on a macroscopic (i.e., bulk) scale. As shown in FIG. 1B, the polymer may be formed into the piezoelectric sheet 4.

Physically deforming the piezoelectric sheet 4 generates charge separation that can be harvested as electricity or electrical energy. For example, attaching an anode and a cathode to the piezoelectric material creates an electrical circuit with an electric potential, voltage [V]. The voltage may be used to perform work (e.g., power an electrical component included in the circuit, charge a battery).

FIG. 1C shows a schematic of comparative example of a conventional energy harvester 10.

As shown in FIG. 1C, the conventional energy harvester 10 consists of one or more single layer piezoelectric sheets 4a-c placed along the bluff body 2, within the flow field of the KVS. The deformation in each of the piezoelectric sheets 4a-c creates an electrical potential that is utilized by a connected electrical circuit. However, the output of the conventional energy harvester 10 is small and limited to small, low-power devices.

Embodiments of the present invention improve the technical field of fluid flow energy harvesters by utilizing a multilayer stack of piezoelectric layers in a configuration that generates more electrical energy with greater efficiency.

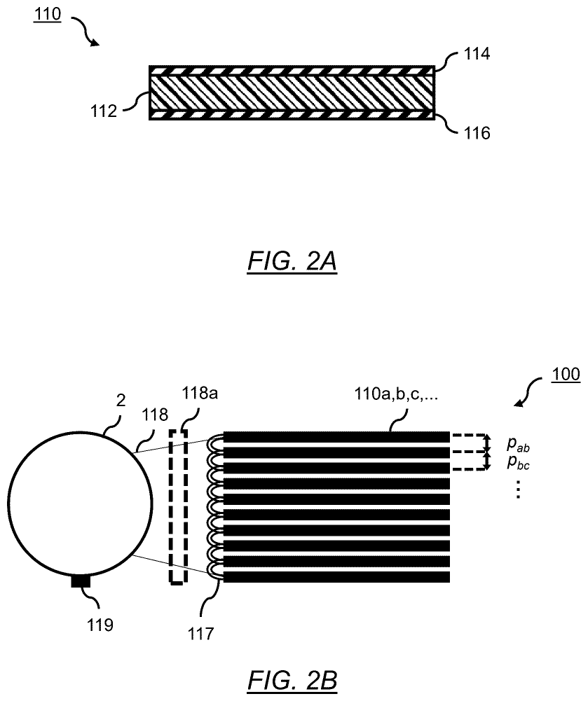

FIG. 2A shows a piezoelectric layer 110, in accordance with one or more embodiments.

As shown in the cross-section view, the piezoelectric layer 110 includes a flexible piezoelectric film substrate 112. In some embodiments, the piezoelectric film substrate 112 comprise a fluorinated polymer. For example, the piezoelectric film substrate 112 may comprises at least one selected from a group consisting of a polyvinylidene fluoride (PVDF) homopolymer, a poly(vinylidene fluoride-co-trifluoroethylene) (P(VDF-TrFE) co-polymer), a poly(vinylidene fluoride-co-chlorofluoroethylene) (P(VDF-CFE) co-polymer), a poly(vinylidene fluoride-co-chlorotrifluoroethylene) (P(VDF-CTFE) co-polymer), a poly(vinylidene fluoride-co-hexafluoropropylene) (P(VDF-HFP) co-polymer), a poly(vinylidene fluoride-co-tetrafluoroethylene) (P(VDF-TFE) co-polymers), a P(VDF-TrFE-CFE) ter-polymer, and a P(VDF-TrFE-CTFE) ter-polymer, a P(VDF-TFE-HFP) ter-polymer, a P(VDF-TFE-CTFE) ter-polymers, and a P(VDF-TFE-CFE) ter-polymer. In some embodiments, the piezoelectric film substrate 110 comprises one selected from a group consisting of a PVDF piezoelectric film, a PVDF copolymer film, a polylactic acid piezo-biopolymer film, a polyurea film, a polyurethane film, a polyamide film, a polyacrylonitrile film, a polyimide, and a polypropylene film.

In some embodiments, the piezoelectric film substrate 112 can be formed of a composite material with a ceramic solid and a polymer matrix, as long as it has sufficient flexibility and mechanical strength for use in the system. The ceramic may be a piezoelectric ceramic. For example, the piezoelectric ceramic may comprise at least one selected from a group consisting of a K0.5 Na0.5 NbO3 (“KNN”), barium titanate, lithium niobate, lithium tetraborate, quartz, Pb(Mg1/3Nb2/3)3-PbTiO3 (“PMN-PT”), Pb(Zn1/3Nb2/3)O3-PbTiO3 (“PZN-PT”), and zirconate titanate (“PZT”). The polymer matrix may or may not comprise a piezoelectric polymer which has a piezoelectricity. Nonlimiting examples for the piezoelectric polymer are fluorinated polymers and lactic acid-based polymers. The polymer having little or no piezoelectricity may be used in combination with the piezoelectric ceramic for power generating efficiency.

Polymer films are flexible and can be easily deformed by low forces such as Karman vortexes. However, generated electricity tends to have high voltage and low current. Therefore, it is more efficient to improve the current value by stacking a large number of thin films and connecting them in parallel, rather than stacking a small number of thick films within a certain width. Therefore, in some embodiments, the piezoelectric film substrate has a thickness in a range between 10 μm and 200 μm.

As shown in FIG. 2A, the piezoelectric layer 110 includes an anode 114 and a cathode 116 that are electrically connected to the piezoelectric film substrate 112. The anode 114 and the cathode 116 comprise at least one selected from a group consisting of carbon-nanotubes (CNTs), graphene, copper, aluminum, silver, gold, and conductive polymer. Alternatively, any conductive material may be used.

In some embodiments, the anode 114 and the cathode 116 cover opposite sides of the piezoelectric film substrate 112 (e.g., the anode 114 covers a first side of the piezoelectric film substrate 112 and the cathode 116 covers a second side of the piezoelectric film substrate 112). In some embodiments, each of the anode 114 and the cathode 116 may be patterned to cover a portion of one side of the piezoelectric film substrate 112 (e.g., a periodic pattern, a symmetrical or asymmetrical pattern, a distributed contiguous pattern).

While FIG. 2A shows the anode 114 and the cathode 116 as contiguous films on opposing sides of the piezoelectric film substrate 112, it will be appreciated that any geometry may be used for the electrodes attached to the piezoelectric film substrate 112.

FIG. 2B shows a multilayer stack 100 of piezoelectric layers 110, in accordance with one or more embodiments.

An energy harvesting system according to one or more embodiments includes a plurality of the piezoelectric layers 110 formed into the multilayer stack 100. The number, n, of piezoelectric layers 110 in the multilayer stack 100 may be any number greater than 2. In some embodiments, the number of piezoelectric layers 110 is determined based on the size and geometry of a bluff body 2. In some embodiments, an overall width of the multilayer stack 100 is equal to or greater than a width of the bluff body 2.

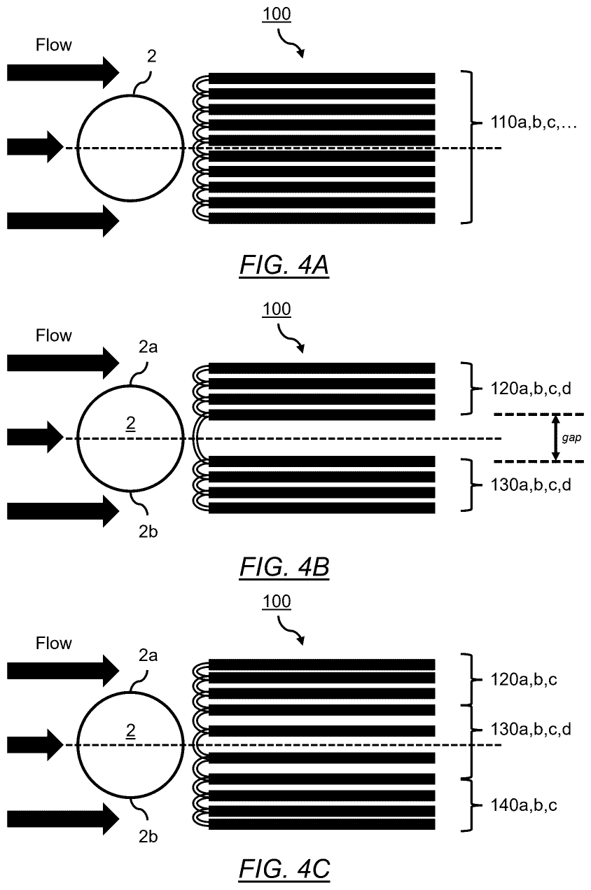

As shown in FIG. 2B, the piezoelectric layers 110 are stacked along a first direction. A separation between adjacent layers is described by a pitch parameter, p. For example, the separation between piezoelectric layer 110a and piezoelectric layer 110b is pitch p_{ab}, the separation between piezoelectric layer 110b and piezoelectric layer 110c is pitch p_{bc}, and so on. The multilayer stack 100 may have a constant pitch between all piezoelectric layers 110a-n (i.e., a pitch of the piezoelectric layers in the multilayer stack is uniform along the first direction) or may have multiple pitch parameters (i.e., a pitch of the piezoelectric layers in the multilayer stack is non-uniform along the first direction). Various configurations are described in further detail below with respect to FIGS. 4A-4C. The pitch may be filled with a material having a higher Poisson ratio than the material formed of the adjacent piezoelectric layers. Examples for the material filling the pitch are rubbers, plastics, and metals. In one or more embodiments, the material filling the pitch is the substance constituting a medium of a flow around the piezoelectric layers, that is the pitch may be a space between the piezoelectric layers.

Each of the piezoelectric layers 110 in the multilayer stack 100 has a thickness. Based on the thickness and composition of a given piezoelectric layer 110, the flexibility of each piezoelectric layer 110 may be different. In some embodiments, a thickness of the piezoelectric layers 110 in the multilayer stack 100 is uniform. In some embodiments, a thickness of the piezoelectric layers 110 in the multilayer stack 100 is non-uniform. For example, the piezoelectric layers 110 may include a first thickness group and a second thickness group where a thickness of the piezoelectric layers in the first thickness group is larger than a thickness of the piezoelectric layers in the second thickness group.

In the multilayer stack 100, the piezoelectric layers 110a-n are electrically connected by jumpers 117. The piezoelectric layers 110a-n may be electrically connected in series, in parallel, or in any combination thereof. For example, the jumpers 117 may be configured in a network to achieve a desired output voltage level and/or a desired output current level. In some embodiments, adjacent piezoelectric layers 110 are electrically connected in parallel along the side closer to the bluff body 2.

The multilayer stack 100 may be connected to a bluff body 2 by a tether 118. The tether 118 may include one or more connectors (e.g., wires, tethers, guide wires) that connect to one or more piezoelectric layers 110 of the multilayer stack 100. For example, the tether 118 may include two wires attached to the multilayer stack 100 (e.g., the outermost layers). In some embodiments, the tether 118 includes a support structure 118a that maintains the pitch of the piezoelectric layers 110 in the multilayer stack 100. In some embodiments, the tether 118 electrically connects the multilayer stack to a terminal 119.

In some embodiments, the terminal 119 includes other electronic circuitry or circuit elements to condition the electricity generated by the piezoelectric layers 110. For example, the terminal 119 may include one or more AC/DC converters (e.g., a rectifier circuit, a half-wave rectifier circuit and full-wave rectifier circuit), voltage regulators (e.g., step voltage regulator), storage devices (e.g., batteries), and/or connections to other electronic equipment (e.g., external controller, load devices to use the electricity).

While FIGS. 2B-4C show a flow direction, a longitudinal axis of the bluff body 2, and a stacking direction of the piezoelectric layers 110 that are mutually perpendicular, it will be appreciated that other configurations are possible. In some embodiments, the longitudinal axis of the bluff body 2 is perpendicular to the first direction but not perpendicular to the flow direction. For example, the longitudinal axis of the bluff body 2 may be set at any angle relative to the flow direction (as long as the piezoelectric layers 110 have space to extend along the direction of flow).

A plurality of multilayer stacks may be deployed along the bluff body 2, within the flow field of the KVS. The number of multilayer stacks and the width of each multilayer stack can be adjusted by the length of the longitudinal axis of the bluff body 2 and the uniformity of the medium that causes KVS. It is preferable to deploy each multilayer stack so that they do not interfere with each other's deformation. The plurality of multilayer stacks may be electrically connected in series, in parallel, or in any combination thereof. For example, the jumpers may be configured in a network to achieve a desired output voltage level and/or a desired output current level.

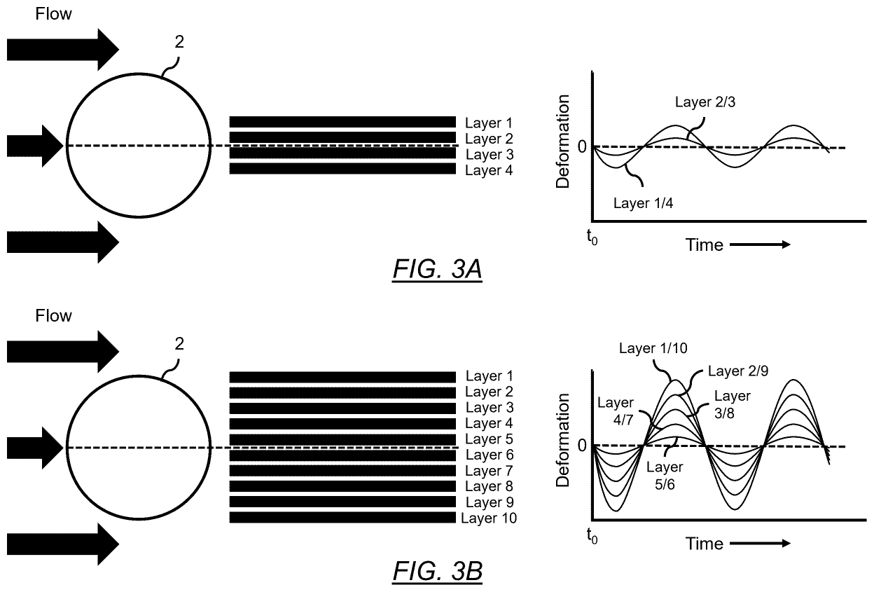

FIGS. 3A-3B show examples of deformation over time in a multilayer stack 100 according to example embodiments.

In FIG. 3A, a multilayer stack 100 includes four piezoelectric layers 110 (i.e., piezoelectric layers 110a-d or layers 1-4, respectively). The layer 1-4 are stacked along a first direction such that each layer extends away from the bluff body 2 along a second direction (e.g., along the direction of flow of a medium). In some embodiments, the first direction and the second direction are perpendicular to each other (e.g., the stacking direction is perpendicular to the flow direction). The dashed line represents an axis of symmetry of the bluff body 2 along the second direction (i.e., a line that passes through the center of the cross-section of the bluff body and along the direction of flow).

As discussed above with respect to FIG. 1A, in response to the flow of a medium around the bluff body 2 along a second direction, a KVS may be formed along the second direction. The eddies that are periodically shed from the bluff body 2 along the direction of the KVS causes the layers 1-4 to deform in a periodic manner. The deformation of the layers 1-4 is shown over a period of time in the inset plot of FIG. 3A. In the non-limiting example shown here, the system is symmetric about the dashed line (i.e., layers 1 and 4 are symmetric and exhibit the same amount of deformation, layers 2 and 3 are symmetric and exhibit the same amount of deformation).

The amount of deformation in each piezoelectric layer 110 is affected by the position of the layer relative to the bluff body 2 and direction of flow. Specifically, the innermost layers of the multilayer stack 100 (i.e., layers 2 and 3) deform less than the outermost layer of the multilayer stack 100 (i.e., layers 1 and 4).

In FIG. 3B, a multilayer stack 100 includes ten piezoelectric layers 110 (i.e., piezoelectric layers 110a-j, or layers 1-10, respectively). The deformation of the layers 1-10 is shown over a period of time in the inset plot of FIG. 3B. Similar to FIG. 3A, the inner layers of the multilayer stack 100 deform less than the outermost layers of the multilayer stack 100 (i.e., layers 1 and 10).

Based on the above, the inventor has found that the arrangement and composition of the multilayer stack 100 may be optimized to control the amount of electricity generated. In other words, controlling the position of each piezoelectric layer 110, withing the multilayer stack 100 and/or relative to the bluff body 2, will affect the amount of the deformation and the corresponding electricity generation from the multilayer stack 100. Similarly, controlling the thickness of each piezoelectric layer 110, withing the multilayer stack 100 and its position relative to the bluff body 2, will affect the amount of the deformation and the corresponding electricity generation from the multilayer stack 100.

FIGS. 4A-4C show examples of a multilayer stack 100, in accordance with one or more embodiments.

In FIG. 4A, the multilayer stack 100 includes ten piezoelectric layers 110a-j. The piezoelectric layers 110a-j are stacked in the first direction with a uniform pitch. The overall width of the multilayer stack 100 in the first direction is equal to or greater than a width of the bluff body 2 in the first direction. By disposing piezoelectric layers 110a-j across the entire width of the bluff body 2 in the first direction, the multilayer stack is able to convert the deformation in all of the curves in the plot of FIG. 3B into electricity.

In FIG. 4B, the multilayer stack 100 includes eight piezoelectric layers divided into two groups, a first group of piezoelectric layers 120a-d and a second group of piezoelectric layers 130a-d, that are separated by a gap. While FIG. 4B shows two groups with the same number of piezoelectric layers, the number of piezoelectric layers 120 in the first group may be different than the number of piezoelectric layers 130 of the second group. Furthermore, while FIG. 4B shows the overall width of the multilayer stack 100 in the first direction being greater than a width of the bluff body 2 in the first direction, the overall width of the multilayer stack 100 may be equal to or less than the width of the bluff body 2 in the first direction.

In some embodiments, the piezoelectric layers 120a-d are stacked in the first direction with a uniform pitch in the first group and the piezoelectric layers 130a-d are stacked in the first direction with a uniform pitch in the second group.

In some embodiments, the piezoelectric layers may include a first edge group (i.e., the piezoelectric layers 120a-d overlapping the first edge 2a along the first direction of the bluff body 2, when viewed along the second direction) and a second edge group (i.e., the piezoelectric layers 130a-d overlapping the second edge 2b along the first direction of the bluff body 2, when viewed along the second direction). The first edge group is separated from the second edge group in the first direction by a gap. When viewed along the second direction, the gap overlaps a center of the bluff body in the first direction (i.e., the gap overlaps the dashed line that is an axis of symmetry of the bluff body 2 along the second direction).

By splitting the multilayers stack 100 into two groups that overlap the edges 2a-b of the bluff body 2 in the first direction, the piezoelectric layers are positioned in regions of the KVS with higher amounts of deformation (e.g., curves for Layers 1/10, Layers 2/9, Layers 3/8, Layers 4/7 in the plot of FIG. 3B). Accordingly, the multilayer stack 100 is able to more efficiently convert energy from the KVS into electricity, relative to the number of piezoelectric layer used.

In some embodiments, the uniform pitch of the first group is different than the uniform pitch of the second group. In other words, the piezoelectric layers may include an upper pitch group and a lower pitch group. A pitch of the piezoelectric layers 120 in the upper pitch group may be larger than a pitch of the piezoelectric layers 130 in the lower pitch group. In some embodiments, the first and/or second groups of piezoelectric layers may have non-uniform pitch.

In some embodiments, a region of the multilayer stack 100 that includes the minimum pitch between the piezoelectric layers (i.e., the smallest pitch or the highest density of piezoelectric layers) overlaps an edge of the bluff body 2 when viewed along the second direction. For example, in FIG. 4B, the first group of piezoelectric layers 120 and the second group of piezoelectric layers group 130 each overlap an edge (2a and 2b, respectively) of the bluff body 2 in the first direction, when viewed along the second direction. Meanwhile, the less dense region (i.e., a region including the gap) overlaps the center of the bluff body in the first direction, when viewed along the second direction.

In other words, in FIG. 4B, the multilayer stack 100 includes a first pitch of the piezoelectric layers closer to a center of the multilayer stack 100 in the first direction and a second pitch of the piezoelectric layers is smaller than the first pitch and closer to an outermost edge of the multilayer stack 100 in the first direction. In some embodiments, the first pitch is the largest pitch of the piezoelectric layers in the multilayer stack 100. Furthermore, in some embodiments, a region that includes the second pitch overlaps an edge of the bluff body 2 when viewed along the second direction. In some embodiments, the multilayer stack includes: an upper layer group which is an upper section (e.g., an upper one third in height of the multilayer stack) of the multilayer stack 100; a middle layer group which is middle section (e.g., a middle one third in height of the multilayer stack) of the multilayer stack 100; and a lower layer group which is lower section (e.g., a lower one third in height of the multilayer stack) of the multilayer stack 100. Furthermore, in some embodiments, a total distance of a pitch of the piezoelectric layers in the middle layer group is larger than a total distance of a pitch of the piezoelectric layers in the upper or lower layer group.

In FIG. 4C, the multilayer stack 100 includes ten piezoelectric layers divided into three groups, a first group of piezoelectric layers 120a-c, a second group of piezoelectric layers 130a-d, and a third group of piezoelectric layers 140a-c. While FIG. 4C shows the first and third groups with the same number of piezoelectric layers, the number of piezoelectric layers in any of the groups may be the same or different from any other group. Furthermore, while FIG. 4C shows the overall width of the multilayer stack 100 in the first direction being greater than a width of the bluff body 2 in the first direction, the overall width of the multilayer stack 100 may be equal to or less than the width of the bluff body 2 in the first direction.

In some embodiments, the first, second, and third groups may each have non-uniform pitch. In other words, rather than the piecewise pattern shown in the examples of FIGS. 2B-4B, the piezoelectric layers of the multilayer stack 100 may be arranged with a continuous density gradient pattern along the first direction.

In some embodiments, each of the first, second, and third groups may characterized by an average pitch value. The average pitch of the first and third groups is less than an average pitch of the second group (i.e., the wider spacing of piezoelectric layers 130a-d). In other words, second group is an upper pitch group and each of the first and third groups is a lower pitch group. In FIG. 4C, the upper pitch group overlaps a center of the bluff body 2 in the first direction when viewed along the second direction. Furthermore, a lower pitch group (either of the first group or the third group) overlaps an edge of the bluff body 2 (edge 2a for the first group or edge 2b for the third group) in the first direction when viewed along the second direction.

By disposing piezoelectric layers with higher density (i.e., lower pitch) in regions that are near to or overlap the edges of the bluff body 2 in the first direction, when viewed in the second direction, the multilayer stack 100 is able to more efficiently convert energy from the KVS into electricity, relative to the number of piezoelectric layer used. In other words, varying the stacking density the piezoelectric layers is another approach for emphasizing regions of the KVS with higher amounts of deformation (e.g., curves for Layers 1/10, Layers 2/9, Layers 3/8, Layers 4/7 in the plot of FIG. 3B).

In FIGS. 4B-4C, the overall pitch of the multilayer stack 100 is non-uniform and symmetric along the first direction, relative to a center of the bluff body in the first direction. However, in some embodiments, the multilayer stack 100 may not be symmetric relative to the center of the bluff body in the first direction (e.g., when groups include different thicknesses/pitches/numbers of piezoelectric layers, when a gap is asymmetrically positioned relative to the center of the bluff body in the first direction).

While FIGS. 2B-4C show the bluff body 2 with a circular cross-section (i.e., a cylinder bluff body), it will be appreciated that the bluff body 2 may take any shape. For example, the bluff body 2 may be a triangular prism, a cuboid, a polygonal prism, a semicircular column, etc. In some embodiments, the bluff body 2 may have a cross-section that is non-uniform along a third direction (e.g., a tapered cylinder or prism). In some embodiments, the bluff body may be a preexisting structure in an environment with a flowing medium (e.g., a building with wind flowing around its sides, an underwater pole in a flowing current).

A method for manufacturing an energy harvesting system that includes a bluff body and a multilayer stack, in accordance with one or more embodiments is following:

A bluff body and piezoelectric layers are obtained. Each piezoelectric layers includes: a flexible piezoelectric film substrate; an anode that covers a first side of the piezoelectric film substrate; and a cathode that covers a second side of the piezoelectric film substrate. A multilayer stack of the piezoelectric layers is assembled by stacking the piezoelectric layers along a first direction.

The piezoelectric layers are electrically connected in parallel. Electrically connecting the piezoelectric layers may be conducted before, during or after stacking the piezoelectric layers as long as it's possible and efficient.

The multilayer stack is attached to the bluff body such that the piezoelectric layers are configured to deform in response to a flow of a medium around the bluff body along a second direction. Attaching the multilayer stack to the bluff body may be conducted before or after electrically connecting the piezoelectric layers as long as it's possible and efficient.

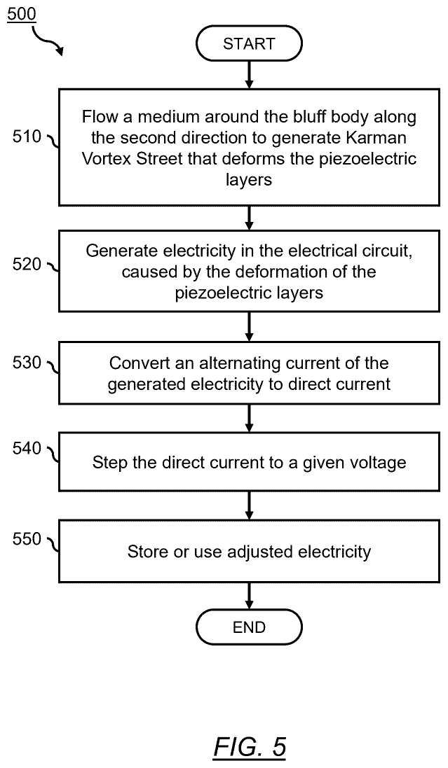

FIG. 5 shows a flowchart of a method for generating electricity using an energy harvesting system that includes a bluff body and a multilayer stack, in accordance with one or more embodiments.

At 510, a medium is flowed around the bluff body along the second direction to generate Karman Vortex Street that deforms the piezoelectric layers.

At 520, the electricity in the electrical circuit, caused by the deformation of the piezoelectric layers, is generated.

At 530, the alternating current generated by the harvester is converted to direct current (e.g., using one or more rectifier circuits). For example, the rectifier circuits may comprise at least one selected from a half-wave rectifier circuit and full-wave rectifier circuit.

At 540, the direct current is stepped to a given voltage (e.g., using one or more switching voltage regulator circuits).

At, 550, the adjusted electricity can be either stored (e.g., in a secondary battery) or used (e.g., by connected electronic devices). For example, the rectifier circuits may comprise at least one selected from lead-acid battery, nickel cadmium battery, nickel metal hydride battery, lithium-ion battery, lithium polymer battery.

Although method 500 has been described with respect to a limited number of examples and operations, those skilled in the art, having benefit of this disclosure, will appreciate that various other embodiments may be devised without departing from the scope of the present disclosure.

Furthermore, while the various blocks in FIG. 5 are presented and described sequentially, one of ordinary skill in the art will appreciate that some or all of the blocks may be executed in different orders, combined, omitted, and some or all of the blocks may be executed in parallel.

Although the disclosure has been described with respect to a limited number of embodiments, those skilled in the art, having benefit of this disclosure, will appreciate that various other embodiments may be devised without departing from the scope of the present invention. Accordingly, the scope of the invention should be limited only by the attached claims.

What is claimed is:

1. An energy harvesting system comprising:
a bluff body; and
a multilayer stack including piezoelectric layers stacked along a first direction,
wherein each piezoelectric layer includes:
a flexible piezoelectric film substrate that extends away from the bluff body along a second direction;
an anode that covers a first side of the piezoelectric film substrate; and
a cathode that covers a second side of the piezoelectric film substrate,
wherein the piezoelectric layers are electrically connected in parallel,
wherein the piezoelectric layers are configured to deform in response to a flow of a medium around the bluff body along the second direction.

2. The energy harvesting system of claim 1,
wherein the piezoelectric film substrate comprises one selected from a group consisting of a fluorinated polymer film, a polylactic acid piezo-biopolymer film, a polyurea film, a polyurethane film, a polyamide film, a polyacrylonitrile film, a polyimide film, and a polypropylene film.

3. The energy harvesting system of claim 2,
wherein the piezoelectric film substrate comprises the fluorinated polymer film, and
wherein the fluorinated polymer film comprises at least one selected from a group consisting of a polyvinylidene fluoride (PVDF) homopolymer, a poly(vinylidene fluoride-co-trifluoroethylene) (P(VDF-TrFE) co-polymer), a poly(vinylidene fluoride-co-chlorofluoroethylene) (P(VDF-CFE) co-polymer), a poly(vinylidene fluoride-co-chlorotrifluoroethylene) (P(VDF-CTFE) co-polymer), a poly(vinylidene fluoride-co-hexafluoropropylene) (P(VDF-HFP) co-polymer), a poly(vinylidene fluoride-co-tetrafluoroethylene) (P(VDF-TFE) co-polymers), a P(VDF-TrFE-CFE) ter-polymer, and a P(VDF-TrFE-CTFE) ter-polymer, a P(VDF-TFE-HFP) ter-polymer, a P(VDF-TFE-CTFE) ter-polymers, and a P(VDF-TFE-CFE) ter-polymer.

4. The energy harvesting system of claim 1,
wherein the piezoelectric film substrate has a thickness in a range between 10 μm and 200 μm.

5. The energy harvesting system of claim 1,
wherein the anode and the cathode comprise at least one selected from a group consisting of carbon-nanotubes (CNTs), graphene, copper, aluminum, silver, gold, and conductive polymer.

6. The energy harvesting system of claim 1,
wherein adjacent piezoelectric layers are electrically connected in parallel along a side closer to the bluff body.

7. The energy harvesting system of claim 1,
wherein a longitudinal axis of the bluff body is perpendicular to the first direction.

8. The energy harvesting system of claim 1,
wherein a pitch of the piezoelectric layers in the multilayer stack is uniform along the first direction.

9. The energy harvesting system of claim 1,
wherein a pitch of the piezoelectric layers in the multilayer stack is non-uniform along the first direction, and
wherein the multilayer stack includes a first pitch of the piezoelectric layers closer to a center of the multilayer stack in the first direction and a second pitch of the piezoelectric layers smaller than the first pitch and closer to an outermost edge of the multilayer stack in the first direction.
